(19) United States
(12) Patent Application Publication
(10) Pub. No.: US 2015/0189793 A1
(43) Pub. Date: Jul. 2, 2015

(54) HEAT DISSIPATION APPARATUS

(71) Applicants: HONG FU JIN PRECISION INDUSTRY (WuHan) CO., LTD., Wuhan (CN); HON HAI PRECISION INDUSTRY CO., LTD., New Taipei (TW)

(72) Inventors: XU LI, Wuhan (CN); ZHI-PING WU, Wuhan (CN); HAI-YUN WANG, Wuhan (CN)

(21) Appl. No.: 14/523,460

(22) Filed: Oct. 24, 2014

(30) Foreign Application Priority Data
Dec. 30, 2013 (CN) 201310742437.8

(51) Int. Cl. H05K 7/20

(52) U.S. Cl. CPC H05K 7/20418; H05K 7/20272

(57) ABSTRACT

A heat dissipation apparatus includes a housing, a heat transfer member, a heat absorption member and a fin group. The housing includes a top plate. The heat transfer member is spaced from the top plate. The heat transfer member and the housing together define a cavity. The heat transfer member defines a receiving space. The receiving space is configured to receive liquid. The heat absorption member is attached to the heat transfer member. The heat absorption member is in heat transferable contact with the electronic element to absorb heat generated by the electronic element and transfer the heat to the heat transfer member. The fin group is received in the cavity and touches the heat transfer member. The fin group dissipates the heat on the heat transfer member.

### CROSS-REFERENCE TO RELATED APPLICATIONS

This application claims priority to Chinese Patent Application No. 201310742437.8 filed on Dec. 30, 2013, the contents of which are incorporated by reference herein.

### FIELD

The present disclosure relates to a heat dissipation apparatus.

### BACKGROUND

Electronic device includes a circuit board and a number of electronic components electrically connected on the circuit board. A fan is employed in the electronic device to dissipate heat generated by the electronic components.

### BRIEF DESCRIPTION OF THE DRAWINGS

Implementations of the present technology will now be described, by way of example only, with reference to the attached figures.

FIG. 1 is an exploded isometric view of a heat dissipation apparatus according to an exemplary embodiment.

FIG. 2 is an isometric view of a heat dissipation plate of the heat dissipation apparatus of FIG. 1.

FIG. 3 is a cross sectional view taken along the line III-III of FIG. 2

FIG. 4 is an isometric view of a heat dissipation apparatus of FIG. 1.

FIG. 5 is similar to FIG. 2, but viewed from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

The term “comprising” means “including, but not necessarily limited to”; it specifically indicates open-ended inclusion or membership in a so-described combination, group, series, and the like.

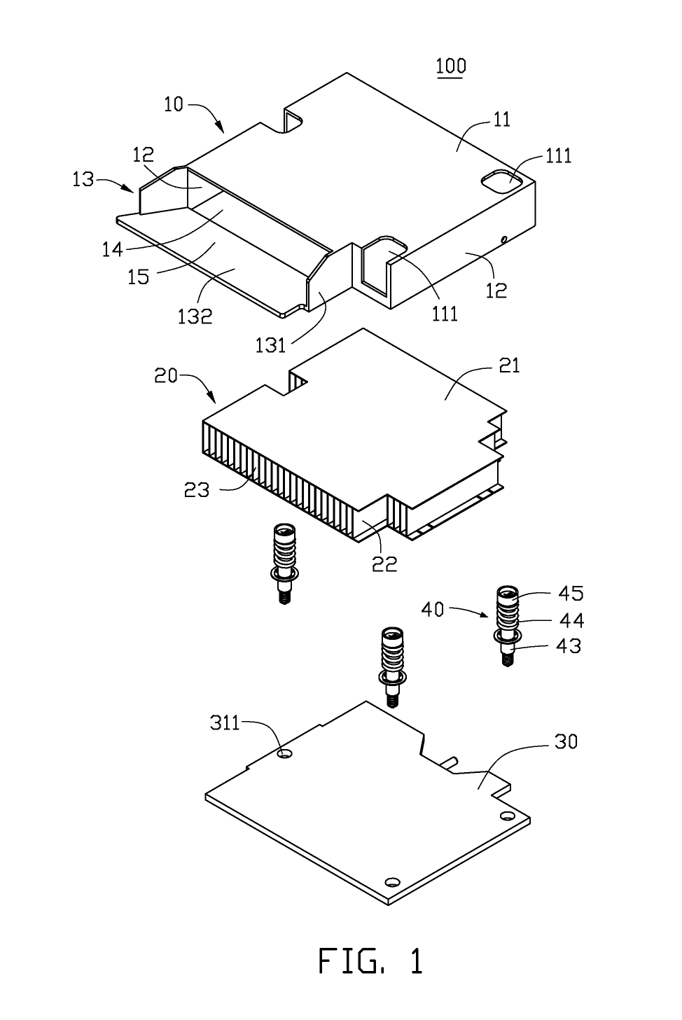

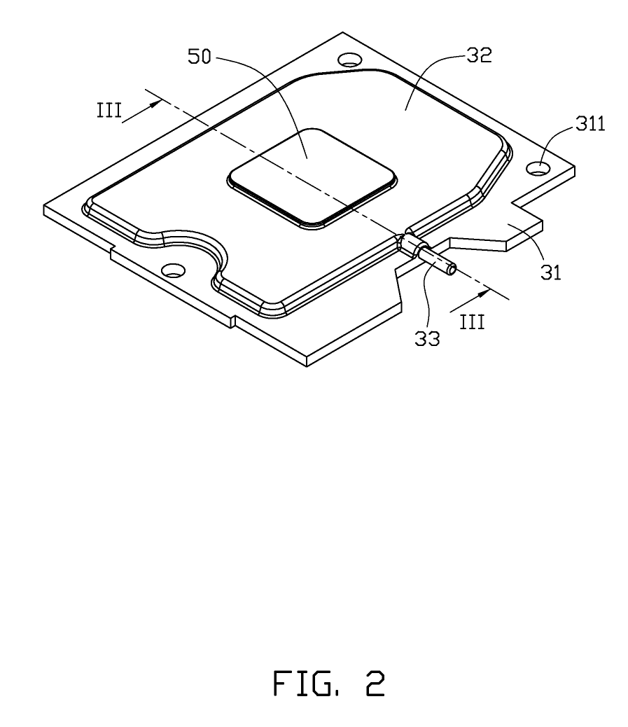

FIGS. 1 and 2 illustrate a heat dissipation apparatus 100 is employed in an electronic device (not shown) to dissipate heat generated by electronic elements (not shown) in the electronic device. The heat dissipation apparatus 100 includes a housing 10, a fin group 20, a heat transfer member 30 and a heat absorption member 50.

The housing 10 includes a top plate 11 and two sidewalls 12. The two sidewalls 12 perpendicularly protrude from two opposite edges of the top plate 11. The heat transfer member 30 is positioned between the two sidewalls 12 and is spaced from the top plate 11. The cooling member 30, the two sidewalls 12 and the top plate 11 together define a cavity 14. The cavity 14 is configured to receive the fin group 21.

The housing 10 further includes a guiding member 13. The guiding member 13 defines an air inlet 15 communicating with the cavity 14. In the embodiment, the guiding member 13 includes two guiding plates 131 and a bottom plate 132. The two guiding plates 131 are perpendicularly attached to the top plate 11. The bottom plate 132 is attached between the edges of the two guiding plates 131 away from the top plate 11. The guiding plate 131 and the bottom plate 132 together define the air inlet 15.

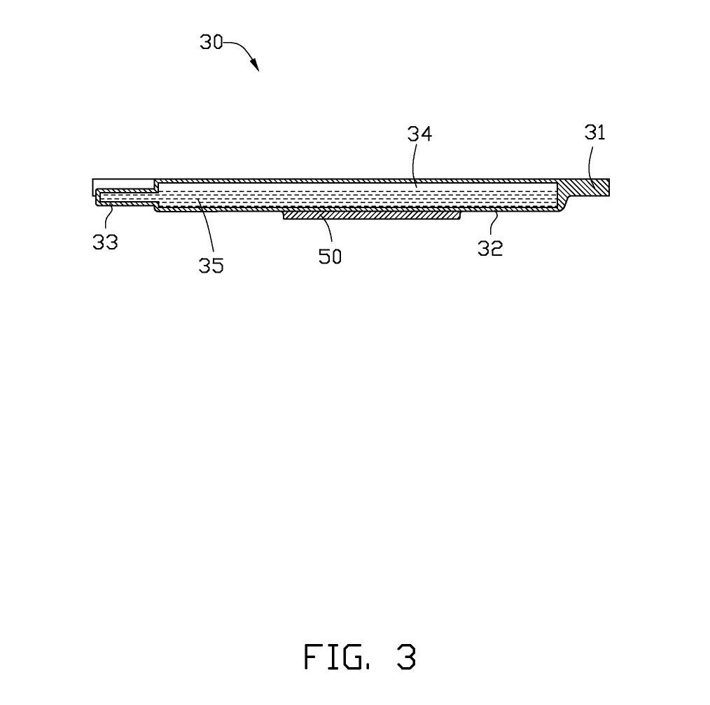

The heat transfer member 30 includes a base plate 31 and a protruding plate 32. The edge of the protruding plate 32 is attached to the base plate 31. FIG. 3 illustrates that the base plate 31 and the protruding plate 32 together define a receiving space 34. The receiving space 34 is configured to receive liquid 35. A guiding tube 33 protrudes from the edge of the protruding plate 31 and communicates with the receiving space 34. The guiding tube 33 is configured to inject liquid 35 to the receiving space 34.

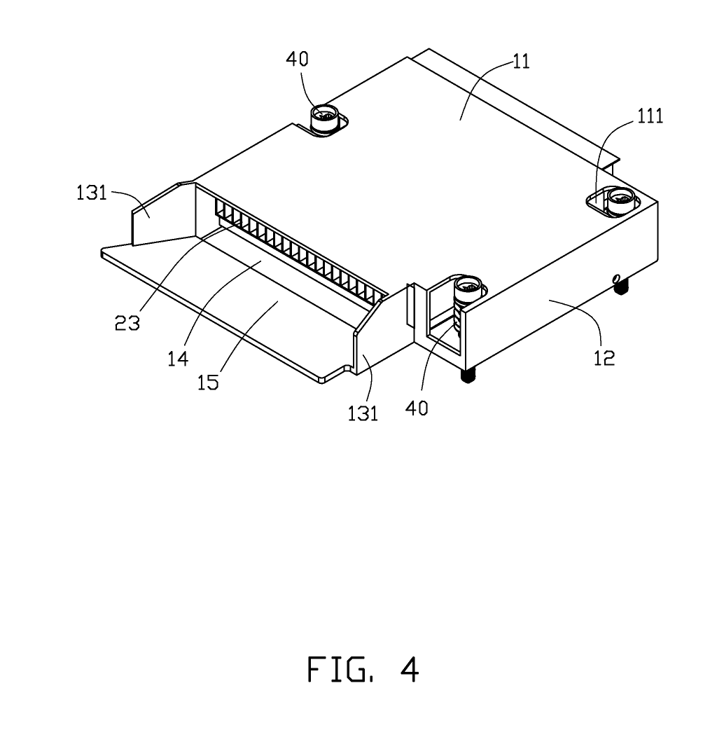

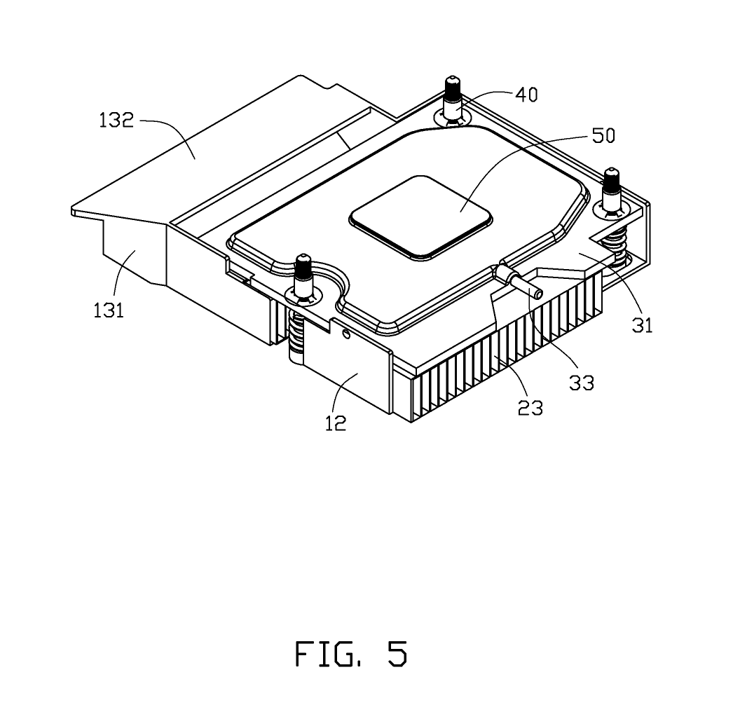

FIGS. 4 and 5 illustrate that the heat absorption member 50 is attached on the protruding plate 32. The heat absorption member 50 is configured to touch the electronic element to absorb the heat generated by the electronic element. The heat is transferred to the protruding plate 32. Then the heat on the protruding plate 32 is absorbed by the liquid 35 and the base plate 31. The fin group 20 absorbs and dissipates the heat transferred by the base plate 31. In the embodiment, the fin group 20 includes two connection plates 21 and a number of fins 22. The fins 22 are attached between the two connection plates 21. The fins 22 are parallel to the sidewall 12. A gap 23 is defined between each fin 22 communicating with the air inlet 15. The air from the air inlet 15 is driven by a fan (not shown) to be passed through the gap 23, from one end of the fin 22 near the air inlet 15 to the other end of the fin 22 away from the air inlet 15. Thus, the heat of the heat absorption member 50 is dissipated and the heat generated by the electronic element can be continuously absorbed by the heat absorption member 50 and dissipated by the airflow from the inlet 15 flowing through the gap 23.

The heat dissipation apparatus 100 further includes a number of fixing members 40. The top plate 11 defines a number of first through holes 111. The base plate 31 defines a number of second through holes 311. The three fixing members 40 pass through the first through holes 111 and the second through holes 311 to attach to the electronic device. In the embodiment, the heat dissipation apparatus 100 includes three fixing members 40. The base plate 31 and the top plate 11 respectively define three second through holes 311 and three first through holes 111. The fixing member 40 includes a fixing piece (not labeled) and an elastic piece 44. The fixing piece includes a pole portion 43 and a collar portion 45. The pole portion 43 passes through the second through hole 311 to attach to the electronic device. The elastic piece 44 is sleeved on the pole portion 43 and is positioned between the collar portion 45 and the base plate 31. The fixing piece 42 is a bolt. The bolt is screwed to a circuit board of the electronic device. Thus, the heat dissipation apparatus 100 is attached to the circuit board by the bolt 42 and the elastic piece 44 is configured to adjust force between the heat dissipation apparatus 100 and the circuit board when the bolt 42 is screwed to the circuit board.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including, the full extent established by the broad general meaning of the terms used in the claims.

What is claimed is:

1. A heat dissipation apparatus comprising:
a housing comprising a top plate;
a heat transfer member spaced from the top plate, the heat transfer member and the housing together defining a cavity, the heat transfer member defining a receiving space, the receiving space configured to receive liquid;
a heat absorption member attached to the heat transfer member and being in heat transferable contact with an electronic element of an electronic device to absorb heat generated by the electronic element and transfer the heat to the heat transfer member; and
a fin group received in the cavity and touching the heat transfer member, the fin group configured to dissipate the heat on the heat transfer member.

2. The heat dissipation apparatus as claimed in claim 1, wherein the fin group comprises a plurality of fins, each two fins defines a gap between the two fins, air passes through the gaps to dissipate the heat.

3. The heat dissipation apparatus as claimed in claim 1, wherein the housing further defines an air inlet communicated with the cavity, an extended direction of the gap is parallel to the air inlet.

4. The heat dissipation apparatus as claimed in claim 3, wherein the housing further comprises two guiding plates and a bottom plate, the two guiding plates are perpendicularly attached to the top plate, the bottom plate is attached between the edges of the two guiding plates away from the top plate, the two guiding plate and the bottom plate together defines the air inlet.

5. The heat dissipation apparatus as claimed in claim 1, wherein the heat transfer member comprises a base plate and a protruding plate, the edge of the protruding plate is attached to the base plate, the base plate and the protruding plate together defines the receiving space.

6. The heat dissipation apparatus as claimed in claim 5, wherein a guiding tube protrudes from the edge of the protruding plate and communicates with the receiving space, the guiding tube is configured to inject liquid to the receiving space.

7. The heat dissipation apparatus as claimed in claim 1, wherein the housing further comprises two sidewalls perpendicularly protruding from two opposite edges of the top plate, the heat transfer member is positioned between the two sidewalls.

8. The heat dissipation apparatus as claimed in claim 1, further comprising a plurality of fixing members, the fixing member is configured to attach the heat transfer member to the electronic device.

9. The heat dissipation apparatus as claimed in claim 8, wherein the fixing member comprises a fixing piece and an elastic piece, the fixing piece comprises a pole portion and a collar portion, the heat transfer member defines a plurality of through holes, the pole portion passes through the through hole to attach to the electronic device, the elastic piece is sleeved on the pole portion and is positioned between the collar portion and the heat transfer member.

10. The heat dissipation apparatus as claimed in claim 9, wherein the fixing piece is a bolt, the bolt is screwed to a circuit board of the electronic device.

11. A heat dissipation apparatus for an electronic device with an electronic element, the heat dissipation apparatus comprising:
a top plate with a first side edge and a second side edge opposite, and parallel, to the first side edge;
a first side plate extending from the first side edge substantially perpendicular to the top plate, the first side plate having a first side plate distal edge furthest from and substantially parallel to the top plate;
a second side plate extending from the second side edge substantially perpendicular to the top plate, the second side plate having a second side plate distal edge furthest from and substantially parallel to the top plate;
a heat transfer member with a first surface and a second surface opposite, and substantially parallel to the first surface, the heat transfer member coupled to the first side plate distal edge and the second side plate distal edge to form a defined space between the top plate and the heat transfer member;
a fin assembly positioned on and in contact with the first surface of the heat transfer member; and
a heat absorption member attached to the second surface of the heat transfer member;
wherein, there is a receiving space defined in the heat transfer member between the first heat transfer member surface and the second heat transfer member surface, with receiving space configured to receive liquid;
wherein, the fin assembly comprises a plurality of substantially parallel plates substantially parallel to the first side plate and the second side plate when the fin assembly is positioned on heat transfer member; and
wherein, the heat dissipation apparatus is positionable relative the electronic device so that the heat absorption member is in heat transferable contact with the electronic element.

12. The heat dissipation apparatus as claimed in claim 11, wherein the fin group comprises a plurality of fins, each two fins defines a gap between the two fins, air passes through the gaps to dissipate the heat.

13. The heat dissipation apparatus as claimed in claim 12, wherein an air inlet is defined between the first side plate and the second side plate, the air inlet is communicated with the gaps, an extended direction of the gap is parallel to the air inlet.

14. The heat dissipation apparatus as claimed in claim 13, wherein two guiding plates are perpendicularly attached to the top plate and a bottom plate is attached between the edges of the two guiding plates away from the top plate, the two guiding plate and the bottom plate together defines the air inlet.

15. The heat dissipation apparatus as claimed in claim 11, wherein the heat transfer member comprises a base plate and a protruding plate, the edge of the protruding plate is attached to the base plate, the base plate and the protruding plate together defines the receiving space.

16. The heat dissipation apparatus as claimed in claim 15, wherein a guiding tube protrudes from the edge of the protruding plate and communicates with the receiving space, the guiding tube is configured to inject liquid to the receiving space.

17. The heat dissipation apparatus as claimed in claim 11, further comprising a plurality of fixing members, the fixing member is configured to attach the heat transfer member to the electronic device.

18. The heat dissipation apparatus as claimed in claim 17, wherein the fixing member comprises a fixing piece and an elastic piece, the fixing piece comprises a pole portion and a collar portion, the heat transfer member defines a plurality of through holes, the pole portion passes through the through hole to attach to the electronic device, the elastic piece abuts against between the collar portion and the heat transfer member.

19. The heat dissipation apparatus as claimed in claim 18, wherein the elastic piece is sleeved on the pole portion.

20. The heat dissipation apparatus as claimed in claim 19, wherein the fixing piece is a bolt, the bolt is screwed to a circuit board of the electronic device.
